(19) United States
(12) Patent Application Publication
(10) Pub. No.: US 2011/0056548 A1
(43) Pub. Date: Mar. 10, 2011

(54) Wafer-Based Solar Cell with Deeply Etched Structure

(75) Inventor: Li-Karn WANG, Taipei City (TW)

(73) Assignee: Li-Karn Wang, Taipei (TW)

(21) Appl. No.: 12/556,130

(22) Filed: Sep. 9, 2009

(51) Int. Cl. H01L 31/0236; H01L 31/02; H01L 31/0216; H01L 31/0264

(52) U.S. Cl. 136/256; 136/252; 136/261

(57) ABSTRACT

The present invention provides a solar cell fabricated with a single-crystalline, polycrystalline or amorphous semiconductor wafer. The semiconductor wafer has etched holes or a groove array on it. The depthes of the holes or grooves are larger than one fourth thickness of the wafer. Or, the bottom areas of the holes or grooves are within 50 micrometers to the opposite side of the wafer. Without forming a buried contact structure, the present invention shortens diffusion distance of carriers, and thus enhances opto-electric conversion efficiency.

### FIELD OF THE INVENTION

The present invention relates to a solar cell; more particularly, relates to providing a solar cell made of a semiconductor wafer having a deeply-etched structure for enhencing opto-electric conversion efficiency without using buried contact.

### DESCRIPTION OF THE RELATED ART

In FIG. 4, a prior art of a solar cell is made of a semiconductor wafer 7 having an N-type semiconductor layer 71 and a P-type semiconductor layer 72 to form a P-N junction 73. The prior art further has a front contact 74 and a rear contact 75. When sun rays are shined on a front-side surface of the solar cell 76, the inlet light panatrates through the front-side surface of the solar cell 76 and is absorbed near the surface with carriers of electrons and holes produced. Then the electrons and the holes are gathered at the front contact 74 and the rear contact 75 to form a terminal voltage difference. But, a part of the inlet light at the front-side surface of the solar cell 76 will be reflected so that energy generation efficiency of the solar cell becomes worse. Hence, generally, the front-side surface of the solar cell 76 is a textured surface; or, an anti-reflective film is coated on the front-side surface of the solar cell 76; or, the above two solutions are both used for anti-reflection. In FIG. 5, when sun rays 8a are shined on a textured surface 77, most part of energy enters into the solar cell and a small part of the sun rays 8a are reflected and then re-inlet into the solar cell to be absorbed for generating energy, where there is a back surface field (BSF) 78 at a rear side for improving efficiency of the solar cell.

However, thickness of the P-type semiconductor layer 72 is almost as thick as that of the whole wafer while the N-type semiconductor layer 71 is far thinner. When sun shines, a few carriers do not have suitable diffusion distance and so some electrons and holes may recombine, which is not good for the electrons and the holes to be gathered at the front contact 74 and the rear contact 75. As a result, opto-electric conversion efficiency of the solar cell is limited with power not so well generated.

A general wafer-based solar cell is made of single-crystalline poly-crystalline or amorphous silicon. Concerning opto-electric conversion efficiency, single-crystalline silicon is better than polycrystalline silicon and amorphous silicon. To solve the problem of the duffusion distance for carriers, the solar cell is usually made into a silicon thin film. Yet, the solar cell of the silicon thin film does not fully absorb and use the sun rays and so the opto-electric conversion efficiency is not good. Furthermore, a single-crystalline structure or a polycrystalline structure is not easily fabricated by a non-silicon semiconductor substrate with the silicon thin film; and so the opto-electric conversion efficiency is not good either. Hence, the prior art does not fulfill all users' requests on actual use.

### SUMMARY OF THE INVENTION

The main purpose of the present invention is to provide a solar cell made of a semiconductor wafer having a deeply-etched structure where recombination of carriers are reduced for enhencing opto-electric conversion efficiency without using buried contact.

To achieve the above purpose, the present invention is a wafer-based solar cell with a deeply etched structure, comprising a semiconductor wafer, a semiconductor layer and a P-N junction, where the semiconductor wafer has a deeply-etched structure while an etched region and a flat region are thus formed; the semiconductor layer is deposed on a surface of the semiconductor wafer; the P-N junction is formed between the semiconductor wafer and the semiconductor layer; and the etched region has a depth larger than one fourth thickness of the semiconductor wafer or the etched region has a bottom within 50 micrometers to an opposite side of the semiconductor wafer. Accordingly, a novel wafer-based solar cell with a deeply etched structure is obtained.

### BRIEF DESCRIPTION OF THE DRAWINGS

The present invention will be better understood from the following detailed descriptions of the preferred embodiments according to the present invention, taken in conjunction with the accompanying drawings, in which

FIG. 1 is the sectional view showing the first preferred embodiment according to the present invention;

FIG. 2A is the view showing the groove array;

FIG. 2B is the view showing the independent holes;

FIG. 3 is the sectional view showing the second preferred embodiment;

FIG. 4 is the view of the prior art; and

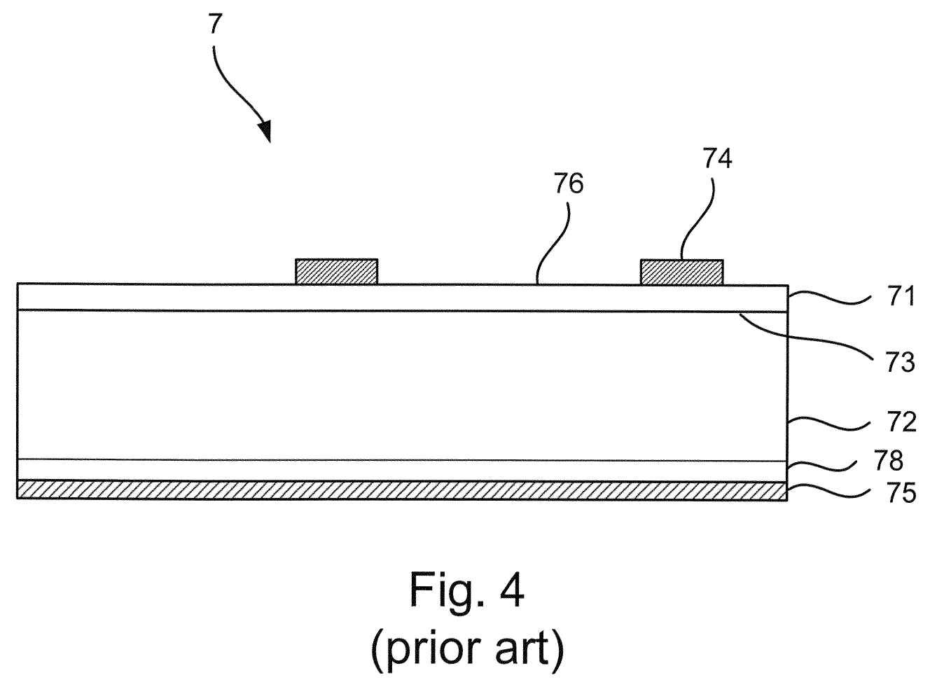

FIG. 5 is the view of the textured surface of the prior art.

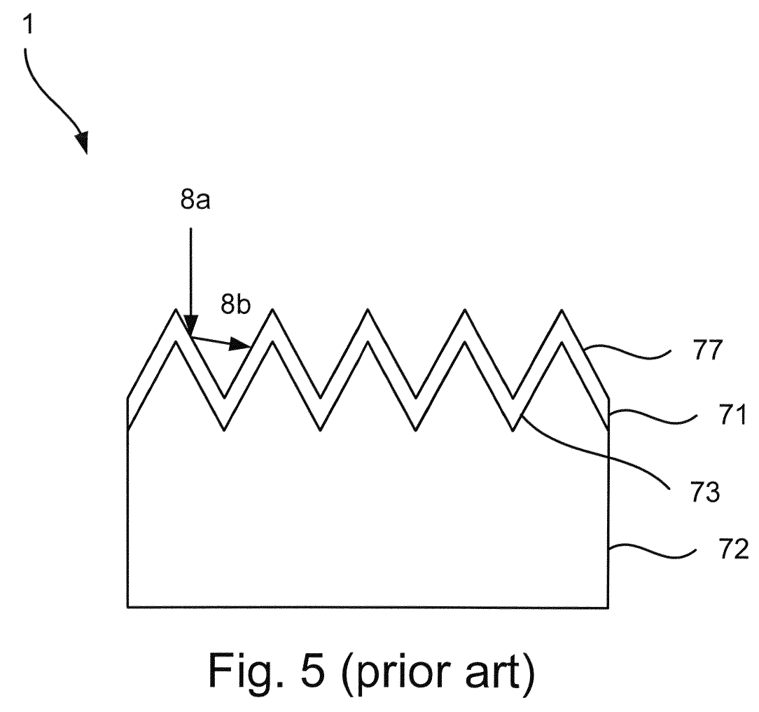

### DESCRIPTION OF THE PREFERRED EMBODIMENTS

The following descriptions of the preferred embodiments are provided to understand the features and the structures of the present invention.

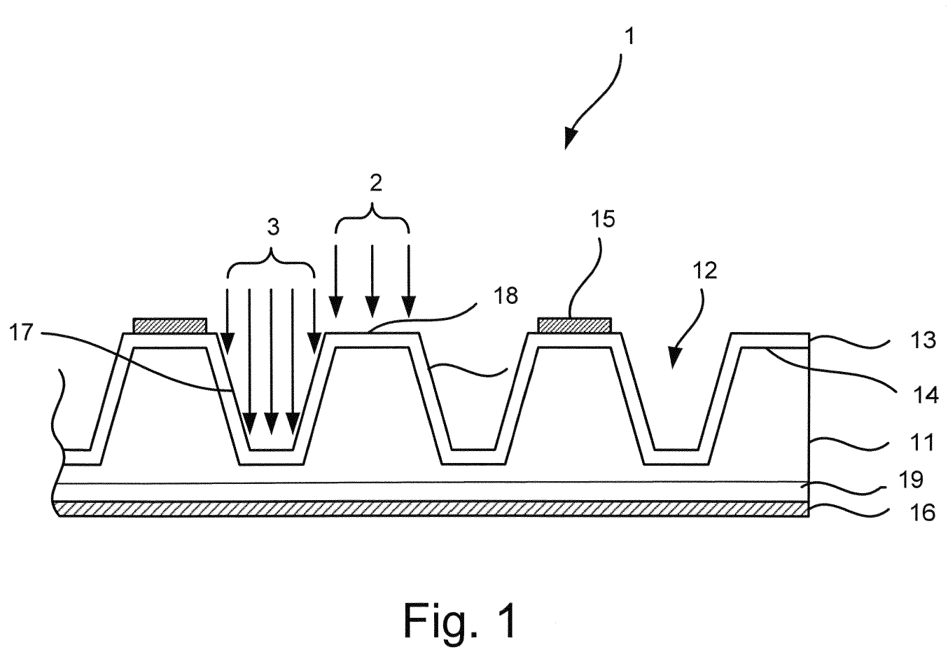

Please refer to FIG. 1, which is a sectional view showing a first preferred embodiment according to the present invention. As shown in the figure, the present invention is a wafer-based solar cell with a deeply etched structure. The solar cell is made of a single-crystalline, polycrystalline or amorphous semiconductor material; and has a deeply-etched structure obtained through wet etching, dry etching, laser scribing or mechanical scribing to form an etched region and a flat region. The etched region has a depth larger than one fourth thickness of the semiconductor wafer; or has a bottom within 50 micrometers to an opposite side of the semiconductor wafer.

A wafer-based solar cell 1 is made of a semiconductor wafer, where the semiconductor wafer is a P-type semiconductor layer 11 made of a group IV element, like silicon or germanium, or its alloy; or a group III or group V element or its alloy. The wafer-based solar cell 1 has a groove array or a plurality of independent holes 12 at a front side to form the etched region and the flat region. A P-N junction 14 is formed by the P-type semiconductor layer 11 together with an N-type semiconductor layer 13 which is formed at the front side. A front contact 15 and a rear contact 16 are respectively coated at the front side and the rear side to direct electric power to an external circuit. Therein, the front contact 15 at the front side is coated on a surface in the etched region 17 or on a surface of the flat region 18; and a back surface field (BSF) 19 is obtained at the rear side of the wafer-based solar cell 1. The side having the etched region and the flat region is further covered with an anti-reflective film; has a textured anti-reflective surface; or, has a textured surface with an anti-reflective film. With the above structure, a novel wafer-based solar cell with a deeply etched structure is obtained.

On using the present invention, if sun rays 2 are shined on the surface of the flat region 18, the sun rays 2 are absorbed near surface with carriers of electrons and holes produced. If the sun rays 3 are shined on the surface in the etched holes 12, the electrons and holes are produced at a thinner place of the semiconductor wafer where diffusion distance of the carriers is shortened to reduce the possibility of recombination of the carriers. Thus, more electric charge is accumulated at the front contact 15 and the rear contact 16 with more power produced. Furthermore, since the etched region 12 has a big opening down to a small bottom, a small opening down to a big bottom or an opening down to a bottom of the same size, illuminated area on a surface of the solar cell is increased with increased area as well for producing electrons and holes. Hence, power generated is increased with enhanced opto-electric conversion efficiency while no buried contact is used.

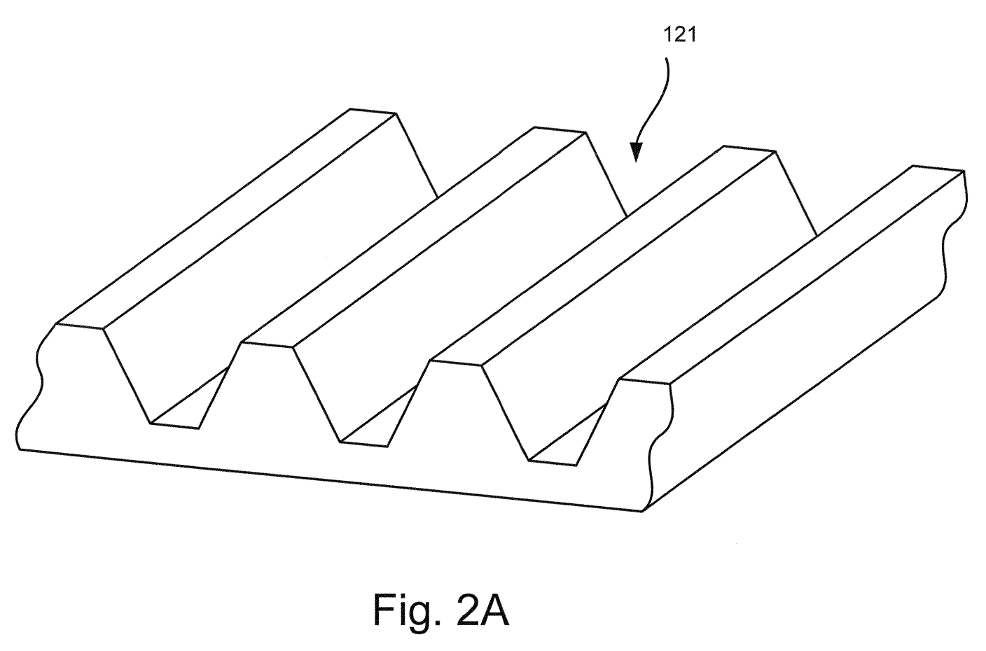

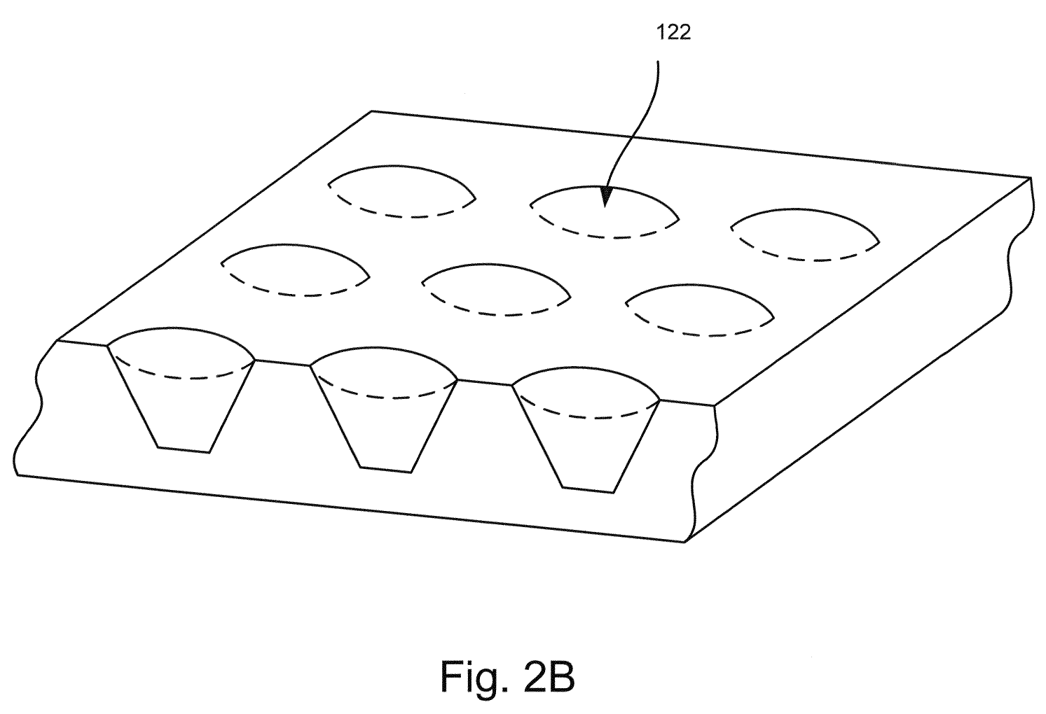

Please further refer to FIG. 2A and FIG. 2B, which are views showing a groove array and independent holes. As shown in the figures, a deeply-etched structure of a wafer-based solar cell according to the present invention comprises a groove array 121 or independent holes 122, where the groove array 121 has straight grooves or curve grooves and the independent holes have geographic openings.

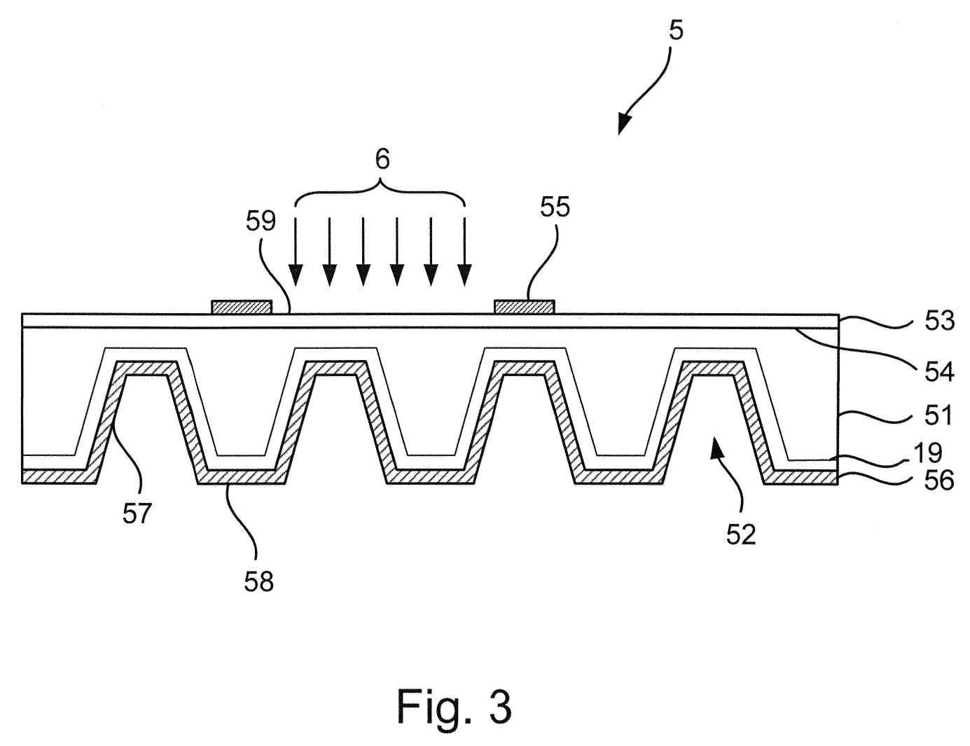

Please refer to FIG. 3, which is a sectional view showing a second preferred embodiment. As shown in the figure, a wafer-based solar cell 5 is made of a semiconductor wafer, where the semiconductor wafer is a P-type semiconductor layer 51 made of a group IV element, like silicon or germanium, or its alloy; or a group III or group V element or its alloy. The wafer-based solar cell 5 has a groove array or a plurality of independent holes 52 at a rear side to form an etched region and a flat region. A P-N junction 54 is formed by the P-type semiconductor layer 51 together with a N-type semiconductor layer 53 which is formed at the front side. A front contact 55 and a rear contact 56 are respectively coated at the front side and the rear side to direct electric power to an external circuit. Therein, the rear contact 56 at the rear side is coated on a surface in the etched region 57, on a surface of the flat region 58 or on a whole surface at the rear side; and a BSF 19 is obtained at the rear side of the semiconductor wafer 5. The front side is further covered with an anti-reflective film; has a textured anti-reflective surface; or, has a textured surface with an anti-reflective film.

On using the present invention, if sun rays 6 are shined on a front-side surface 59 at the illuminated side, the rear contact 56 is very close to the N-type semiconductor layer 53 due to the deeply-etched structure 52 for reducing the possibility of recombination of electrons and holes. Thus, electrons and holes are separately accumulated at the front contact 55 and the rear contact 56 with more power produced and opto-electric conversion efficiency enhenced. Furthermore, since the etched region 52 has a big opening down to a small bottom, a small opening down to a big bottom or an opening down to a bottom of the same size, illuminated area on a surface of the solar cell 5 is increased while areas for producing electrons and holes are increased as well. Hence, power generated is increased without using buried contact.

Although the above semiconductor wafers are made of P-type semiconductors with deeply-etched structures used to improve opto-electric conversion efficiency, the deeply-etched structure can also be applied to semiconductor wafers made of N-type semiconductors having the like structures as shown in FIG. 1 and FIG. 3.

To sum up, the present invention is a wafer-based solar cell with a deeply etched structure, where a solar cell is made of a semiconductor wafer having a deeply-etched structure; and recombination of carriers are reduced by the deeply-etched structure for enhencing opto-electric conversion efficiency without using buried contact.

The preferred embodiments herein disclosed are not intended to unnecessarily limit the scope of the invention. Therefore simple modifications or variations belonging to the equivalent of the scope of the claims and the instructions disclosed herein for a patent are all within the scope of the present invention.

What is claimed is:

1. A wafer-based solar cell with a deeply etched structure, comprising
a semiconductor wafer, said semiconductor wafer having a deeply-etched structure to obtain an etched region and a flat region;
a semiconductor layer, said a semiconductor layer being formed on semiconductor layer being formed on a surface of said semiconductor wafer; and
a P-N junction, said P-N junction being obtained between said semiconductor wafer and said semiconductor layer,
wherein said etched region has a depth larger than one fourth thickness of said semiconductor wafer.

2. The solar cell according to claim 1,
wherein said semiconductor wafer is a P-type semiconductor and said semiconductor layer is an N-type semiconductor.

3. The solar cell according to claim 1,
wherein said semiconductor wafer is an N-type semiconductor and said semiconductor layer is a P-type semiconductor.

4. The solar cell according to claim 1,
wherein said deeply-etched structure are obtained through a method selected from a group consisting of wet etching, dry etching, laser scribing and mechanical scribing.

5. The solar cell according to claim 1,
wherein said etched region comprises independent holes.

6. The solar cell according to claim 1,
wherein said etched region comprises a groove array.

7. The solar cell according to claim 1,
wherein said deeply-etched structure is obtained at a front side of said semiconductor wafer.

8. The solar cell according to claim 1,
wherein said deeply-etched structure is obtained at a rear side of said semiconductor wafer.

9. The solar cell according to claim 1,
wherein said etched region has a bottom within 50 micrometers to an opposite side of said semiconductor wafer.

10. The solar cell according to claim 1,
wherein said semiconductor wafer and said semiconductor layer are made of a material selected from a group consisting of an element and an alloy of said element; and
wherein said element is selected from a group consisting of a group IV element, a group III element and a group V element.

11. The solar cell according to claim 1,
wherein said group IV element is selected from a group consisting of silicon and germanium.

12. The solar cell according to claim 1,
wherein a front side of said semiconductor wafer and a rear side of said semiconductor wafer separately have a metal contact to direct electric power to an external circuit.

13. The solar cell according to claim 1,
wherein a metal contact is coated on a surface in said etched region at a side of said semiconductor wafer; and a back surface field (BSF) is obtained at an opposite side of said semiconductor wafer.

14. The solar cell according to claim 1,
wherein a metal contact is coated on a surface of said flat region at a side of said semiconductor wafer; and a BSF is obtained at an opposite side of said semiconductor wafer.

15. The solar cell according to claim 1,
wherein said etched region has a shape selected from a group consisting of a big opening down to a small bottom, a small opening down to a big bottom and an opening down to a bottom of the same size.

16. The solar cell according to claim 1,
wherein said side of said semiconductor wafer having said etched region and said flat region is further covered with an anti-reflective film.

17. The solar cell according to claim 1,
wherein said side of said semiconductor wafer having said etched region and said flat region has a textured anti-reflective surface.

18. The solar cell according to claim 1,
wherein said side of said semiconductor wafer having said etched region and said flat region has a textured surface with an anti-reflective film.
